(19) United States
(12) Patent Application Publication
(10) Pub. No.: US 2024/0113257 A1
(43) Pub. Date: Apr. 4, 2024

(54) LIGHT-EMITTING DIODE AND LIGHT-EMITTING DEVICE

(71) Applicant: Quanzhou sanan semiconductor technology Co., Ltd., Fujian (CN)

(72) Inventors: Wenhao GAO, Fujian (CN); Qian LIANG, Fujian (CN); Chihcheng HSU, Fujian (CN); Yenchin WANG, Fujian (CN); Huanshao KUO, Fujian (CN); Jinghua CHEN, Fujian (CN); Yuren PENG, Fujian (CN)

(73) Assignee: Quanzhou sanan semiconductor technology Co., Ltd., Fujian (CN)

(21) Appl. No.: 18/353,100

(22) Filed: Jul. 16, 2023

(30) Foreign Application Priority Data
Sep. 30, 2022 (CN) 202211211872.3

(51) Int. Cl. H01L 33/14; H01L 33/06; H01L 33/30

(52) U.S. Cl. CPC H01L 33/14; H01L 33/06; H01L 33/30

(57) ABSTRACT

The invention discloses a light-emitting diode and a light-emitting device. The light-emitting diode includes a semiconductor epitaxial stack having first and second surfaces opposite to each other and including a first-type semiconductor layer, an active layer, and a second-type semiconductor layer stacked in sequence in a direction from the first surface to the second surface. The active layer includes n periods of quantum well structure, and each period of quantum well structure includes a well layer and a barrier layer deposited sequentially. A first spacer layer is disposed between the first-type semiconductor layer and the active layer, and a ratio of a thickness (nm) of the first spacer layer to a current density (A/cm²) of the light-emitting diode ranges from 0 to 10. In the invention, the thickness of the first spacer layer is adjusted according to the current density of the light-emitting diode to improve the luminous efficiency of the light-emitting diode.

### CROSS-REFERENCE TO RELATED APPLICATION

This application claims the priority benefit of China application serial no. 202211211872.3, filed on Sep. 30, 2022. The entirety of the above-mentioned patent application is hereby incorporated by reference herein and made a part of this specification.

### BACKGROUND OF THE INVENTION

### Field of the Invention

The invention relates to the field of semiconductor manufacturing and, in particular, to a light-emitting diode and a light-emitting device.

### Description of Related Art

At present, light-emitting diodes still face many technical challenges, one of which is the efficiency droop effect of light-emitting diodes. Specifically, when light-emitting diodes are operated in a low current density range, they produce one peak of external quantum efficiency (EQE). However, as the current density of the light-emitting diodes continues to be increased, EQE is decreased, and this phenomenon is the efficiency droop effect of the light-emitting diodes.

Generally, in order to make the light-emitting diodes emit light with high brightness, the current density of the light-emitting diodes is usually in the operating range of high current density. Due to the efficiency droop effect mentioned above, the EQE of the light-emitting diodes operating in the range of high current density is limited, and the luminous efficiency of the light-emitting diodes may not be further improved.

### SUMMARY OF THE INVENTION

In order to improve the luminous efficiency of light-emitting diodes, the invention provides a light-emitting diode. The light-emitting diode includes: a semiconductor epitaxial stack having a first surface and a second surface opposite to each other and including a first-type semiconductor layer, an active layer, and a second-type semiconductor layer stacked in sequence in a direction from the first surface to the second surface. The active layer includes n periods of quantum well structure, and each period of quantum well structure includes a well layer and a barrier layer deposited sequentially. A first spacer layer is disposed between the first-type semiconductor layer and the active layer, and a ratio of a thickness (nm) of the first spacer layer to a current density (A/cm²) of the light-emitting diode ranges from 0 to 10.

The invention further provides a light-emitting diode. The light-emitting diode includes: a semiconductor epitaxial stack having a first surface and a second surface opposite to each other and including a first-type semiconductor layer, an active layer, and a second-type semiconductor layer stacked in sequence in a direction from the first surface to the second surface. The active layer includes n periods of quantum well structure, and each period of quantum well structure includes a well layer and a barrier layer deposited sequentially. A first spacer layer is disposed between the first-type semiconductor layer and the active layer. The light-emitting diode has a first side, a second side, a third side, and a fourth side surrounding in turn, wherein the first side is parallel to the third side, the second side is parallel to the fourth side, and a length of the first side is greater than or equal to a length of the second side. When a size of the second side is greater than 100 μm, a thickness of the first spacer layer ranges from 50 nm to 120 nm; or when the size of the second side is less than or equal to 100 μm, the thickness of the first spacer layer ranges from 0 nm to 50 nm.

The invention further provides a light-emitting device including a drive unit and a light-emitting diode. The drive unit is electrically connected to the light-emitting diode, and the light-emitting diode has a first surface and a second surface opposite to each other and includes a first-type semiconductor layer, an active layer, and a second-type semiconductor layer stacked in sequence in a direction from the first surface to the second surface. The active layer includes n periods of quantum well structure, and each period of quantum well structure includes a well layer and a barrier layer deposited sequentially. A first spacer layer is disposed between the first-type semiconductor layer and the active layer, and a ratio of a thickness (nm) of the first spacer layer to a current density (A/cm²) of the light-emitting diode ranges from 0 to 10.

In the light-emitting diode and the light-emitting device according to the embodiments of the invention, the thickness of the first spacer layer in the light-emitting diode may be designed according to different operating ranges of the current density or chip sizes of the light-emitting diode, in order to implement the more ideal EQE of the light-emitting diode, and further improve the luminous efficiency of the light-emitting device. The light-emitting diode in the light-emitting device may have ideal luminous efficiencies under different operating ranges of current densities.

### BRIEF DESCRIPTION OF THE DRAWINGS

FIG. 1 is a schematic diagram of the epitaxial structure mentioned in Embodiment 1 of the invention.

FIG. 2 is a schematic structural diagram of the light-emitting diode mentioned in Embodiment 1 of the invention.

FIG. 3 to FIG. 4 are structural schematic diagrams during the preparation process of the light-emitting diode mentioned in Embodiment 2 of the invention.

FIG. 5 is a schematic structural diagram of the light-emitting diode mentioned in Embodiment 3 of the invention.

FIG. 6 is a schematic structural diagram of the light-emitting diode mentioned in Embodiment 4 of the invention.

FIG. 7 is a schematic structural diagram of the micro light-emitting element mentioned in Embodiment 4 of the invention.

FIG. 8 to FIG. 14 are structural schematic diagrams during the preparation process of the micro light-emitting element mentioned in Embodiment 5 of the invention.

FIG. 15 is a schematic structural diagram of the light-emitting device mentioned in Embodiment 6 of the invention.

### DESCRIPTION OF THE EMBODIMENTS

### Embodiment 1

The present embodiment provides a light-emitting diode. The thickness of the first spacer layer is adjusted according to the operating current density of the light-emitting diode or the size of the light-emitting diode, so as to achieve the luminous efficiency of the light-emitting diode.

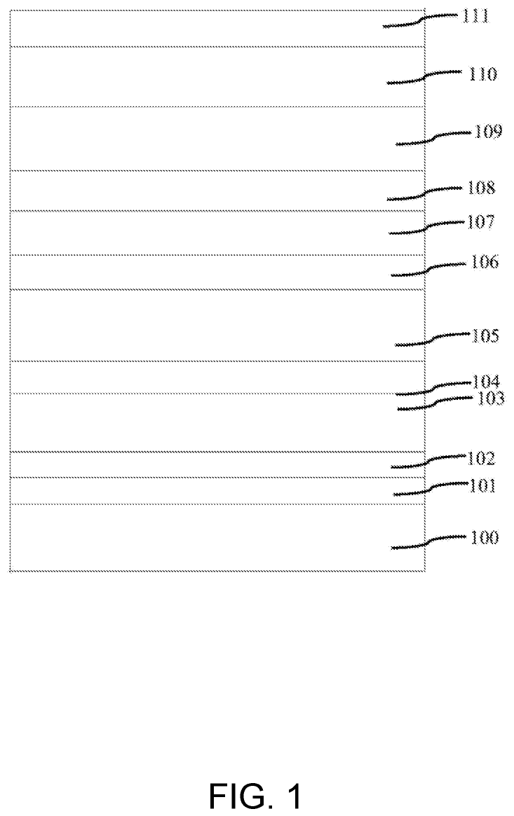

FIG. 1 is a schematic diagram of a light-emitting diode epitaxial structure of a preferred embodiment, and the light-emitting diode epitaxial structure includes: a growth substrate 100; and a semiconductor epitaxial stack including a first current spreading layer 104, a first cladding layer 105, a first spacer layer 106, an active layer 107, a second spacer layer 108, a second cladding layer 109, a second current spreading layer 110, and a second ohmic contact layer 111 stacked in sequence on the growth substrate 100.

Specifically, referring to FIG. 1, the material of the growth substrate 100 includes, but is not limited to, GaAs, and other materials such as GaP, InP, etc., may also be used. In the present embodiment, the GaAs growth substrate 100 is taken as an example. Optionally, a buffer layer 101, an etch stop layer 102, and a first ohmic contact layer 103 are sequentially disposed between the growth substrate 100 and the first current spreading layer 104; wherein since the lattice quality of the buffer layer 101 is better than the lattice quality of the growth substrate 100, growing the buffer layer 101 on the growth substrate 100 is conducive to eliminating the influence of the lattice defects of the growth substrate 100 on the semiconductor epitaxial stack. The etch stop layer 102 is used as a stop layer for chemical etching in later steps. In some optional embodiments, the etch stop layer 102 is an n-type etch stop layer with the material of n-GaInP. In order to facilitate subsequent removal of the growth substrate 100, the thickness of the etch stop layer 102 is controlled within 500 nm, more preferably within 200 nm. In some optional embodiments, the first ohmic contact layer 103 is made of GaAs material with a thickness ranging from 10 nm to 100 nm and a doping concentration ranging from 1E18/cm³ to 10E18/cm³, preferably 2E18/cm³, to achieve better ohmic contact results.

The semiconductor epitaxial stack has a first surface and a second surface opposite to each other, and includes a first-type semiconductor layer, an active layer, and a second-type semiconductor layer stacked in sequence in the direction from the first surface to the second surface. The first-type semiconductor layer and the second-type semiconductor layer may provide electrons or holes via n-type doping or p-type doping respectively. The n-type semiconductor layer may be doped with an n-type dopant such as Si, Ge, or Sn, and the p-type semiconductor layer may be doped with a p-type dopant such as Mg, Zn, Ca, Sr, C, or Ba. When the first-type semiconductor layer is an n-type semiconductor layer, the second-type semiconductor layer is a p-type semiconductor layer; and when the first-type semiconductor layer is a p-type semiconductor layer, the second-type semiconductor layer is an n-type semiconductor layer. The first-type semiconductor layer, the active layer, and the second-type semiconductor layer may specifically be formed from materials such as AlGaInN, GaN, AlGaN, AlInP, AlGaInP, GaAs, or AlGaAs. In the present embodiment, preferably, the first-type semiconductor layer is the n-type semiconductor layer.

The first-type semiconductor layer and the second-type semiconductor layer respectively include the first cladding layer 105 and the second cladding layer 109 providing electrons or holes to the active layer 107, such as AlGaInP or AlInP or AlGaAs. More preferably, when the material of the active layer 107 is AlGaInP, AlInP serves as the first cladding layer 105 and the second cladding layer 109 to provide electrons and holes. In order to improve the uniformity of current spreading, the first-type semiconductor layer and the second-type semiconductor layer further include the first current spreading layer 104 and the second current spreading layer 110. Since the mobility of holes is less than that of electrons, electrons and holes tend to recombine and emit light in the active region near the end of the p-type cladding layer, resulting in a waste of area in the active region. Therefore, the internal quantum efficiency of the light-emitting chip is reduced. In order to adjust the recombination and light emission positions of electrons and holes of the light-emitting diode in the active region (MQW) to fully utilize the area of the active region, in the present embodiment, the first spacer layer 106 exists between the first cladding layer 105 and the active layer 107; and the second spacer layer 108 exists between the second cladding layer 109 and the active layer 107.

The first current spreading layer 104 has the function of spreading current, and the spreading ability thereof is related to thickness. In the present embodiment, the preferred material is Al_{y1}Ga_{1-y1}InP, the thickness is 2500 nm to 4000 nm, and the n-type doping concentration is 2E17/cm³ to 4E18/cm³, preferably between 4E17/cm³ and 2E18/cm³. The common n-type doping is Si doping, and the doping of equivalent replacement of other elements is not excluded.

The first spacer layer 106 is located between the first cladding layer 105 and the active layer 107, the preferred material is Alₐ₁Ga₁₋ₐ₁InP, the thickness of the first spacer layer 106 is preferably 120 nm or less, the Al component content a1 ranges from 0.2 to 1; in the present embodiment, the first spacer layer 106 is preferably n-type doped, and the n-type doping concentration is less than 2E17/cm³.

The first spacer layer 106 functions to limit carrier injection into the active layer 107. By adjusting the thickness of the first spacer layer according to the different current densities of the light-emitting diodes, electrons and holes of the light-emitting diode may be adjusted to recombine and emit light in the active region (MQW) to fully utilize the area of the active region, thereby achieving the object of improving the luminous efficiency of the light-emitting diode. Therefore, in the present embodiment, it is proposed that the ratio of the thickness (nm) of the first spacer layer 106 to the current density (A/cm³) of the light-emitting diode ranges from 0 to 10; preferably, the ratio of the thickness (nm) of the first spacer layer 106 to the current density (A/cm³) of the light-emitting diode ranges from 0 to 5. Under low current density conditions, for example, the current density is less than 10 A/cm³, preferably, the ratio of the thickness (nm) of the first spacer layer 106 to the current density (A/cm³) of the light-emitting diode ranges from 0 to 3, preferably 0 to 2; under medium and high current density conditions, for example, the current density is greater than 10 A/cm³, preferably, the ratio of the thickness (nm) of the first spacer layer 106 to the current density (A/cm³) of the light-emitting diode ranges from 0 to 10, more preferably from 1 to 5; or 1.5 to 8, to effectively control the recombination and light emission positions of electrons and holes of the light-emitting diode in the active region (MQW), so as to fully utilize the area of the active region. Therefore, the object of improving the luminous efficiency of the light-emitting diode is achieved.

In some optional embodiments, the current density of the light-emitting diode using the epitaxial structure of the present embodiment is greater than 10 A/cm³, the thickness of the first spacer layer 106 is preferably 50 nm to 120 nm; the length of at least one side of the light-emitting diode is greater than 100 μm.

In some optional embodiments, the current density of the light-emitting diode using the epitaxial structure of the present embodiment is less than or equal to 10 A/cm³, the thickness of the first spacer layer 106 is preferably 0 nm to 50 nm; preferably, the length of at least one side of the light-emitting diode is less than or equal to 100 μm.

In the present embodiment, the thickness of the first spacer layer may be adjusted according to the size of the chip. The light-emitting diode has a first side, a second side, a third side, and a fourth side surrounding in turn, wherein the first side is parallel to the third side, the second side is parallel to the fourth side, and a length of the first side is greater than or equal to a length of the second side. When the size of the second side is greater than 100 μm, the thickness of the first spacer layer is 50 nm to 120 nm; or when the size of the second side is less than or equal to 100 μm, the thickness of the first spacer layer is 0 nm to 50 nm. By adjusting the thickness of the first spacer layer according to the size of the chip, the recombination and light emission positions of electrons and holes of the light-emitting diode may be effectively adjusted in the active region (MQW) to fully utilize the area of the active region, thereby achieving the object of improving the luminous efficiency of the light-emitting diode.

The first cladding layer 105 functions to provide electrons for the active layer, its preferred material is AlInP, and its thickness is 300 nm to 1500 nm. The common n-type doping is Si doping, and the doping of equivalent replacement of other elements is not excluded.

The active layer 107 provides a light radiation area for the recombination of electrons and holes, and different materials may be selected according to different emission wavelengths. The active layer 107 may be a periodic structure of single quantum well or multiple quantum wells. In the present embodiment, the active layer 107 is a quantum well structure with n periods, and each quantum well structure includes a well layer and a barrier layer deposited in sequence, wherein the barrier layer has a larger bandgap than the well layer. By adjusting the composition ratio of the semiconductor material in the active layer 107, the radiation of light of a target wavelength is expected. The active layer 107 is a material layer providing electroluminescent radiation, such as AlGaInP or AlGaAs, more preferably AlGaInP, which is a single quantum well or multiple quantum wells. In the present embodiment, preferably, the semiconductor epitaxial stack is composed of AlGaInP-based material, and the active layer radiates light with a wavelength of 550 nm 750 nm.

The period number n of the quantum well structure in the present embodiment is 1 to 100, preferably 2 to 50. The well layer is composed of AlₓGa₁₋ₓInP material; the barrier layer is composed of Al_{y}Ga_{1-y}InP material, wherein 0≤x≤y≤1. The thickness of the well layer is 2 nm to 25 nm, preferably 8 nm to 20 nm; the thickness of the barrier layer is 2 nm to 25 nm, preferably 10 nm to 20 nm. The Al component content y of the barrier layer ranges from 0.3 to 0.85.

The second spacer layer 108 is located on the active layer 107, the material of the second spacer layer 108 is preferably Al_{b2}Ga_{1-b2}InP, the thickness of the second spacer layer 108 is preferably 300 nm or less, and the range of the Al component content b1 of the second spacer layer 108 is 0.2 to 1. Preferably, the Al component content b1 ranges from greater than 0.5 to less than or equal to 1; and the doping concentration is less than 2E17/cm³.

The second-type semiconductor layer includes the second cladding layer 109, the second current spreading layer 110, and the second ohmic contact layer 111; wherein the function of the second cladding layer 109 is to provide holes for the active layer 107, the preferred material is AlInP, and the thickness is 300 nm to 1500 nm; the p-type doping is usually Mg doping, and the doping of equivalent replacement of other elements is not excluded.

The second current spreading layer 110 has the function of spreading current, and the spreading ability thereof is related to thickness. Therefore, in the present embodiment, the thickness thereof may be selected according to specific device sizes, and the preferred thickness is controlled at 300 nm or above and 12000 nm or less. In the present embodiment, preferably, the thickness of the second current spreading layer 110 is 500 nm to 10000 nm. In the present embodiment, the preferred material is GaP, the p-type doping concentration is 6E17/cm³ to 2E18/cm³, the p-type doping is usually magnesium doping or carbon doping, and doping of equivalent replacement of other elements is not excluded.

The second ohmic contact layer 111 forms ohmic contact with the second electrode 204, the preferred material is GaP, the doping concentration is 1E19/cm³, more preferably 5E19/cm³ or more, so as to achieve better ohmic contact. The thickness of the second ohmic contact layer 111 shown is preferably 40 nm or more and 150 nm or less. In the present embodiment, preferably, the thickness of the second ohmic contact layer 110 is 60 nm.

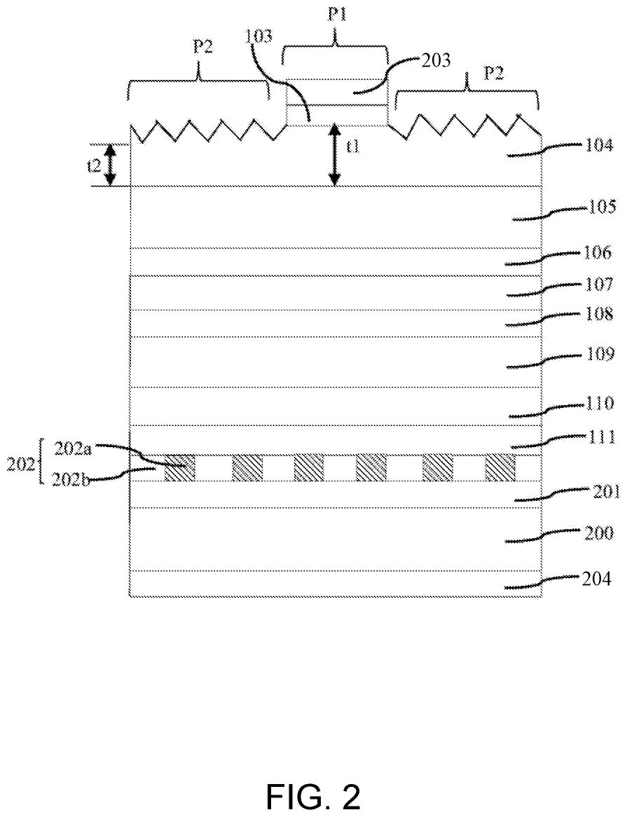

FIG. 2 shows a schematic diagram of a light-emitting diode. The light-emitting diode adopts the epitaxial structure shown in FIG. 1, the current density of the light-emitting diode is greater than 10 A/cm³, the size of the light-emitting diode is preferably greater than 100 μm, that is, the length of at least one side of the light-emitting diode is greater than 100 μm, preferably 300 μm or more. The light-emitting diode is mainly used in fields such as outdoor display screens, plant lighting, and stage lights. The thickness of the first spacer layer in the present embodiment is 50 nm to 120 nm; preferably 60 nm or more and 100 nm or less to effectively adjust the recombination and light emission positions of electrons and holes of the light-emitting diode in the active region (MQW) to fully utilize the area of the active region, thereby achieving the object of improving the luminous efficiency of the light-emitting diode.

The light-emitting diode includes a substrate 200, the semiconductor epitaxial stack is bonded on the substrate 200 via a bonding layer 201, the semiconductor epitaxial stack includes the second ohmic contact layer 111, the second current spreading layer 110, the second cladding layer 109, the second spacer layer 108, the active layer 107, the first spacer layer 106, the first cladding layer 105, the first current spreading layer 104, and the first ohmic contact layer 103 sequentially stacked on the substrate 200.

The substrate 200 is an electrically conductive substrate, and the electrically conductive substrate may be silicon, silicon carbide, or a metal substrate, and the metal substrate is preferably copper, tungsten, or molybdenum substrate. In order to support the semiconductor epitaxial stack with sufficient mechanical strength, the thickness of the substrate 200 is preferably 50 μm or more. In addition, in order to facilitate machine processing of the substrate 200 after bonding to the semiconductor epitaxial stack, the thickness of the substrate 200 is preferably not more than 300 μm. In the present embodiment, preferably, the substrate 200 is silicon substrate.

A first electrode 203 is disposed on the first ohmic contact layer 103, and ohmic contact is formed between the first electrode 203 and the first ohmic contact layer 103 to implement current flow. Only the portion of the first ohmic contact layer 103 vertically below the first electrode 203 is remained. The first current spreading layer 104 includes two portions in the horizontal direction, that is, a portion P1 located below the first electrode 203, and a portion P2 not located below the first electrode 203 is exposed and defined as a light-emitting surface. The light-emitting surface of the first current spreading layer 104 may be formed around the first electrode 203. In some optional embodiments, the light-emitting surface may be further formed into a patterned surface or a roughened surface via an etching process, wherein the patterned surface may be etched to obtain a pattern. The roughened surface may have a regular surface structure or any irregular surface micro-nano structure, and the roughened surface or the patterned surface is essentially so that light of the light-emitting layer may escape more readily to improve light extraction efficiency. Preferably, the light-emitting surface is a roughened surface, and the height difference (or difference in elevation) of the surface structure formed by the roughening is less than 1 micron, preferably 10 nm to 300 nm.

The first current spreading layer 104 includes a second surface of the portion P1 located only below the first electrode 203, and the second surface is not roughened due to being protected by the first electrode 203. Due to the roughening process, the level of the roughened surface of the first current spreading layer 104 is substantially lower than the level of the second surface (interface) located below the first electrode 203.

Specifically, as shown in FIG. 2, in the present embodiment, the first current spreading layer 104 includes the portion P1 located below the first electrode 203 and the portion P2 not located below the first electrode 203, the first current spreading layer 104 has a first thickness t1 at the portion P1 covered by the electrodes, and the first current spreading layer 104 not covered by the first electrode has a second thickness t2. Preferably, the first thickness t1 is 1.5 μm to 2.5 μm, and the second thickness t2 is 0.5 μm to 1.5 μm. The thickness t1 of the P1 portion is greater than the thickness t2 of the P2 portion. Preferably, the second thickness t2 is less than the first thickness t1 by at least 0.3 μm.

A mirror layer 202 may be provided between the semiconductor epitaxial stack and the substrate 200. The mirror layer 202 includes a P-type ohmic contact metal layer 202a and a dielectric material layer 202b, the two corporate to form ohmic contact with the second ohmic contact layer 110 on the one hand and are also used to reflect the light emitted by the active layer 106 to the light exit surface of the first current spreading layer 104 or the sidewall of the semiconductor epitaxial stack to emit light.

The light-emitting diode further includes the second electrode 204. In some embodiments, the second electrode 204 is located at the back surface of the substrate 200. Alternatively, the second electrode 204 is located on the substrate 200 on the same side as the semiconductor epitaxial stack.

The first electrode 203 and the second electrode 204 include transparent conductive material and/or metal material. The transparent conductive material includes a transparent conductive layer, such as ITO or IZO, and the metal material includes at least one of GeAuNi, AuGe, AuZn, Au, Al, Pt, and Ti.

### Embodiment 2

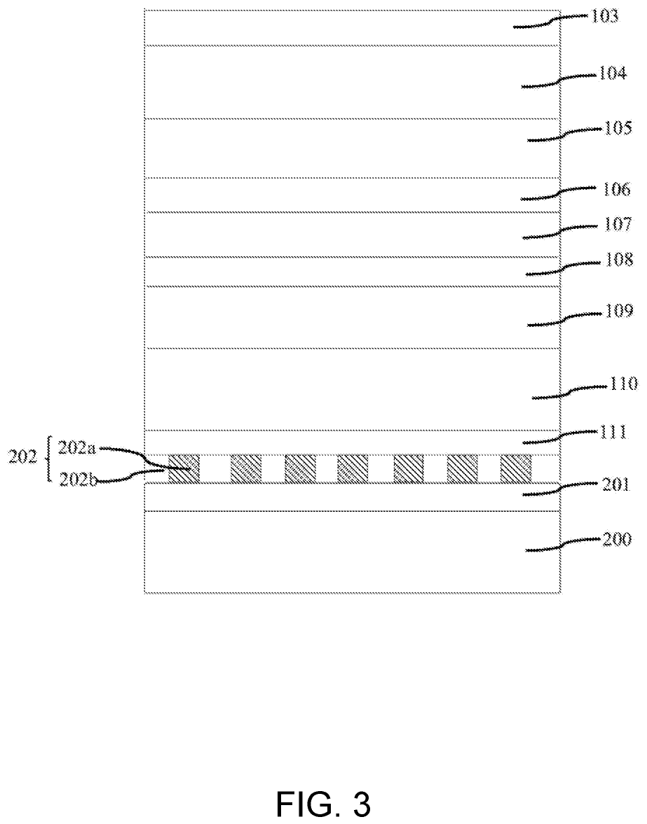

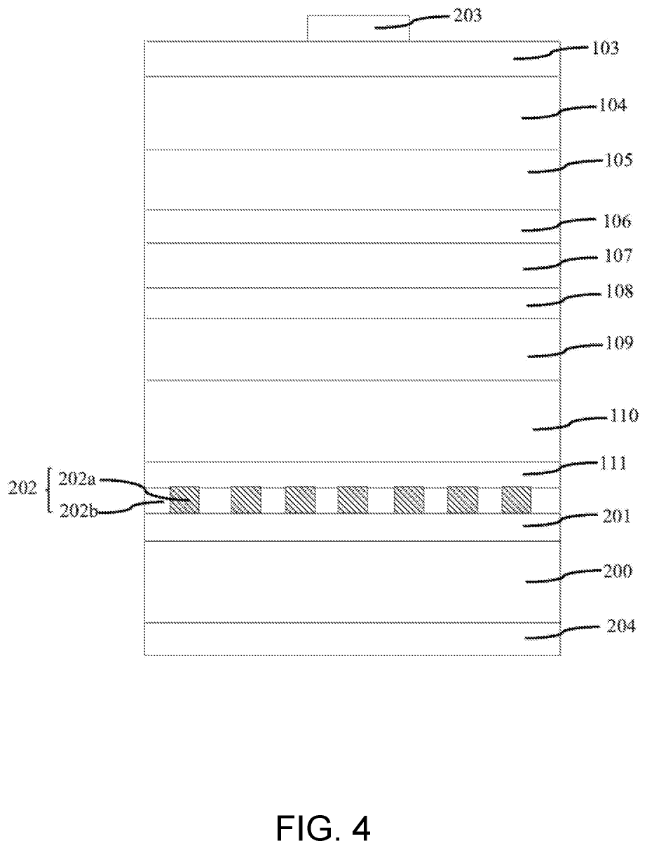

FIG. 3 to FIG. 4 show schematic diagrams of the manufacturing process of the light-emitting diode according to Embodiment 1. The manufacturing method of the light-emitting diode of the present embodiment is described in detail below with reference to the schematic diagrams.

First, referring to FIG. 1, an epitaxial structure is provided, which specifically includes the following steps: the growth substrate 100 is provided, and a semiconductor epitaxial stack is epitaxially grown by an epitaxial process such as MOCVD. The semiconductor epitaxial stack includes the buffer layer 101 and the etch stop layer 102 sequentially stacked on the surface of the growth substrate 100 for removing the epitaxial growth substrate 100 and the first ohmic contact layer 103, the first current spreading layer 104, the first cladding layer 105, the first spacer layer 106, the active layer 107, the second spacer layer 108, the second cladding layer 109, the second current spreading layer 110, and the second ohmic contact layer 111 grown subsequently.

Next, the semiconductor epitaxial stack is transferred onto the substrate 200, the growth substrate 100 is removed, and the structure shown in FIG. 3 is obtained. Specifically, the following steps are included. A mirror layer 202 is manufactured at the second ohmic contact layer 111 and includes a ohmic contact metal layer 202a and a dielectric material layer 202b, both of which corporate to form ohmic contact with the second ohmic contact layer 111 on one hand and to reflect the light emitted downward by the active layer on the other hand. The substrate 200 is provided, a metal bonding layer 201 is disposed on the substrate 200, the metal bonding layer 201 are bonded with the mirror layer 202, the growth substrate 100 is removed, and when the growth substrate 100 is GaAs, the growth substrate 100 may be removed by the wet etching process until the first ohmic contact layer 103 is exposed.

Next, as shown in FIG. 4, the first electrode 203 is formed on the first ohmic contact layer 103, the first electrode 203 forms good ohmic contact with the first ohmic contact layer 103, and the second electrode 204 is formed on the back side of the substrate 200, whereby conduction current may be passed between the first electrode 203 and the second electrode 204 and the semiconductor epitaxial stack. The substrate 200 has a certain thickness capable of supporting all the layers thereon.

Then, a mask is formed to cover the first electrode 203, and the first ohmic contact layer 103 around the first electrode 203 is exposed; an etching process is performed to etch and remove the first ohmic contact layer 103 around the first electrode 203, so that the ohmic contact layer 103 not located under the first electrode 203 is completely removed, and at the same time, the first current spreading layer 104 is exposed, and then the first current spreading layer 104 is etched to form a patterned or roughened surface, forming the structure shown in FIG. 2. The removal process of the ohmic contact layer and the roughening treatment of the first current spreading layer 104 may be the same step or a multi-step wet etching process. The wet etching solution may be an acidic solution, such as hydrochloric acid, sulfuric acid, or hydrofluoric acid or citric acid, or any other preferred chemical reagents.

Lastly, a unitized invisible light-emitting diode is obtained by processes such as etching and splitting according to size requirements.

The light-emitting diode obtained by the preparation method in the present embodiment is mainly used in fields such as outdoor display screens, plant lighting, stage lights, and the current density thereof used is greater than 10 A/cm³, the thickness of the first spacer layer is 50 nm to 120 nm, preferably 60 nm or more and 100 nm or less, to effectively control the recombination and light emission positions of electrons and holes of the light-emitting diode in the active region (MQW), in order to fully utilize the area of the active region, so as to improve the luminous efficiency of the light-emitting diode.

### Embodiment 3

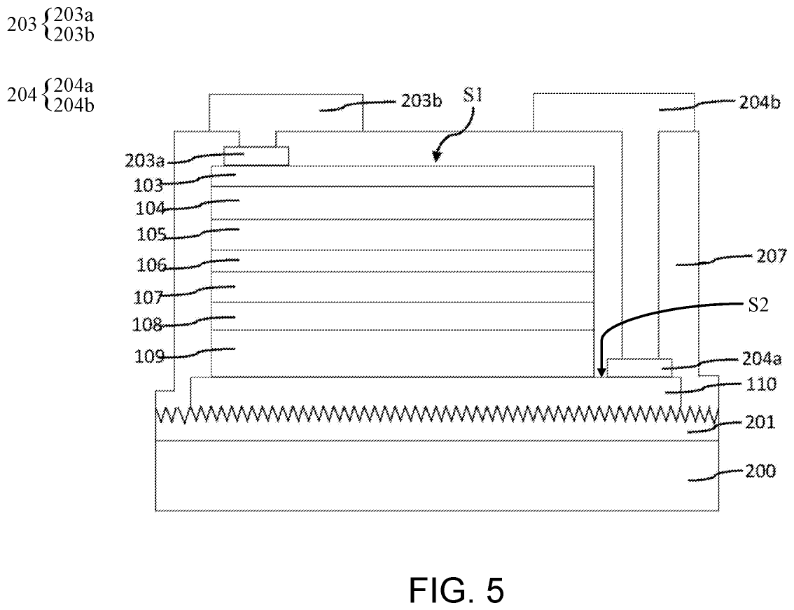

FIG. 5 shows a schematic diagram of a light-emitting diode in another embodiment, and the light-emitting diode adopts the epitaxial structure shown in FIG. 1. The current density of the light-emitting diode in the present embodiment is less than or equal to 10 A/cm³, preferably greater than 5 A/cm³, and the light-emitting diode in the present embodiment is mainly used in TVs and panels. The size of the light-emitting diode in the present embodiment is preferably less than 100 μm and greater than 50 μm. That is, the length of at least one side of the light-emitting diode is greater than 50 μm and less than 100 μm. The thickness of the first spacer layer of the light-emitting diode in the present embodiment is 0 nm to 50 nm, preferably 10 nm or more, more preferably 20 nm or more and 45 nm or less, to effectively adjust the recombination and light emission positions of electrons and holes of the light-emitting diode in the active region (MQW) under this current density range, in order to fully utilize the area of the active region, so as to improve the luminous efficiency of the light-emitting diode.

The light-emitting diode is a flip-chip light-emitting diode. As shown in FIG. 5, the light-emitting diode includes the substrate 200. The substrate 200 is a transparent substrate, preferably a sapphire substrate in the present embodiment. The semiconductor epitaxial stack is bonded to the substrate 200 via the bonding layer 201, the bonding layer 201 is a transparent bonding layer, the semiconductor epitaxial stack includes a first mesa S1 and a second mesa S2, and the mesa S2 is formed by a recessed second-type semiconductor layer; the first electrode 203 and the second electrode 204 include ohmic contact portions 203a and 204a and pad electrodes 203b and 204b, the ohmic contact portions 203a and 204a are formed on the first mesa S1 and the second mesa S2 to form ohmic contacts with the first-type semiconductor layer and the second-type semiconductor layer respectively. A rough structure is formed on the surface of the second current spreading layer 110 to facilitate the bonding of the bonding layer 201 on the surface of the semiconductor epitaxial stack, thereby implementing the bonding of the semiconductor epitaxial stack on the transparent substrate.

In order to improve the reliability of the micro light-emitting diode, an insulating protective layer 207 is provided on the first mesa S1, the second mesa S2, and the side walls of the micro light-emitting diode. The insulating protective layer has a single-layer or multi-layer structure, and is formed by at least one material of SiO₂, SiNₓ, Al₂O₃, and Ti₃O₅. In some optional embodiments, the insulating protective layer 207 is a Bragg protective layer structure. For example, the insulating protective layer 207 is formed by stacking the two materials Ti₃O₅ and SiO₂ alternately. In the present embodiment, the material of the insulating protective layer 207 may be SiNx or SiO₂, and the thickness is 1 μm or more.

The current density of the light-emitting diode in the present embodiment is less than or equal to 10 A/cm³, preferably the thickness of the first spacer layer of the light-emitting diode is 0 nm to 50 nm, preferably 20 nm or less, 45 nm or less, to effectively adjust the recombination and light emission positions of electrons and holes of the light-emitting diode in the active region (MQW) under this current density range, in order to fully utilize the area of the active region, so as to improve the luminous efficiency of the light-emitting diode. In this way, the light-emitting diode may achieve higher luminous efficiency under the operating range of the current density.

### Embodiment 4

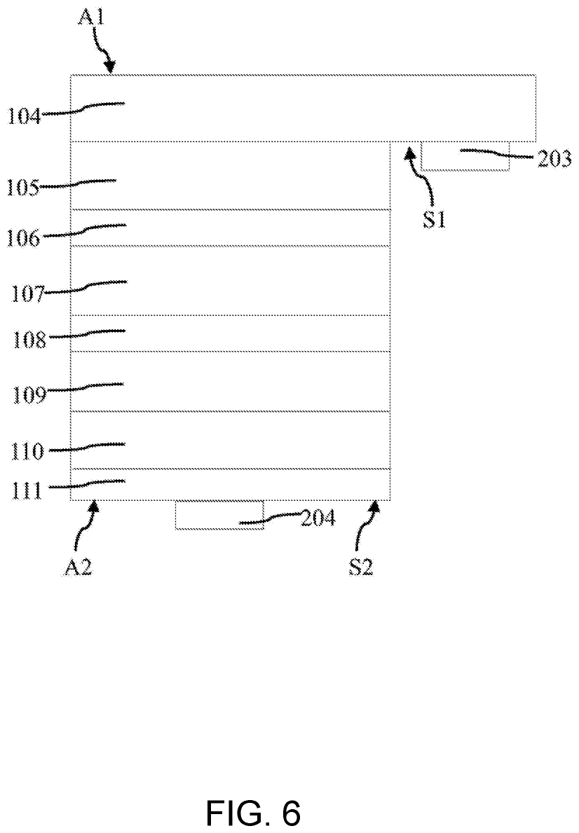

FIG. 6 shows a schematic diagram of a light-emitting diode in another embodiment, and the light-emitting diode adopts the epitaxial structure shown in FIG. 1. In the present embodiment, the light-emitting diode is a micro light-emitting diode, the current density of the micro light-emitting diode is less than 10 A/cm³, more preferably the current density is less than 5 A/cm³, the micro light-emitting diode is mainly used in fields such as TVs, panels, vehicle displays, and wearables. The size of the micro light-emitting diode is preferably less than or equal to 50 μm. That is, the length of at least one side of the micro light-emitting diode is less than or equal to 50 μm. The thickness of the first spacer layer of the light-emitting diode in the present embodiment is 0 nm to 50 nm, preferably 0 nm to 20 nm, more preferably 0 nm to 10 nm, in order to implement the higher luminous efficiency of the micro light-emitting diode under the condition of low current density.

The micro light-emitting diode includes: a semiconductor epitaxial stack, including a first-type semiconductor layer, a second-type semiconductor layer, and an active layer 107 located between the first-type semiconductor layer and the second-type semiconductor layer; the first mesa S1 is formed by the first-type semiconductor layer exposed by the recess of the semiconductor epitaxial stack, and the second mesa S2 is formed by the second-type semiconductor layer, the first electrode 203 is formed on the first mesa S1 and electrically connected to the first-type semiconductor layer; and the second electrode 204 is formed on the second mesa S2 and electrically connected to the second-type semiconductor layer.

In the present embodiment, the first-type semiconductor layer includes the first current spreading layer 104, the first cladding layer 105, and the first spacer layer 106; wherein the first current spreading layer 104 has the function of spreading current, and the spreading ability thereof is related to thickness. In the present embodiment, the preferred material is Alₓ₁Ga₁₋ₓ₁InP, the thickness is 2500 nm to 5000 nm, and the n-type doping concentration is 2E18/cm³ to 5E18/cm³. X1 in Alₓ₁Ga₁₋ₓ₁InP is between 0.3 and 0.7, to ensure the light transmittance of the n-type current spreading layer. The n-type current spreading layer 104 is in ohmic contact with the first electrode 203 to form an electrical connection; a side of the first current spreading layer 104 away from the active layer provides a light exit surface. The function of the first cladding layer 105 is to provide electrons for the MQW, the preferred material is AlInP, and the thickness is 200 nm to 1200 nm; the common n-type doping is Si doping, and the doping of equivalent replacement of other elements is not excluded. The first spacer layer 106 is located between the first cladding layer 105 and the active layer 107, the preferred material is AlGa₁₋ₓ₁InP, and the thickness of the first spacer layer 106 is preferably 0 nm to 50 nm, preferably 0 nm to 20 nm. The range of Al component content a1 is 0.2 to 1; the doping concentration is less than 21E17/cm³.

The second-type semiconductor layer includes the second spacer layer 108, the second cladding layer 109, the second current spreading layer 110, and the second ohmic contact layer 111; the second spacer layer 108 is located between the active layer 107 and the second cladding layer 109, and the material of the second spacer layer 109 is preferably Al_{b2}Ga_{1-b2}InP. The thickness of the second spacer layer 108 is preferably 300 nm or less, and the Al component content b1 of the second spacer layer 107 ranges from 0.3 to 1; the doping concentration is less than 2E17/cm³.

The function of the second cladding layer 109 is to provide holes for the active layer 107, the preferred material is AlInP, and the thickness is 200 nm to 1200 nm; the common P-type doping is Mg doping, and the doping of equivalent replacement of other elements is not excluded.

The second current spreading layer 110 has the function of spreading current, and the spreading ability thereof is related to thickness. Therefore, in the present embodiment, the thickness thereof may be selected according to specific device size, and the preferred thickness is controlled at 200 nm or above and 1500 nm or less. In the present embodiment, preferably, the thickness of the second current spreading layer 110 is 300 nm to 1000 nm. In the present embodiment, the preferred material is GaP, the p-type doping concentration is 9E17/cm³ to 4E18/cm³, the p-type doping is usually C doping, and doping of equivalent replacement of other elements is not excluded.

The second ohmic contact layer 111 covers the second current spreading layer 110, the preferred material is Gap, the thickness is 30 nm to 100 nm, the doping concentration is 5E18/cm³ to 5E19/cm³, the preferred doping concentration is 9E18/cm³ or more, so as to form good ohmic contact with the second electrode 204. The second ohmic contact layer 111 is in ohmic contact with the second electrode 204 to form electrical connection.

The active layer 107 is a multiple quantum well, and the material is a structure of repeated stacked wells and barriers of AlₓGa₁₋ₓInP/Al_{y}Ga_{1-y}InP (0≤x≤y≤1). In the present embodiment, the number of periods of the quantum well structure is 2 to 20, preferably 2 to 15, the thickness of the well layer is 3 nm to 7 nm; the thickness of the barrier layer is 4 nm to 8 nm.

The conductive metal of the first electrode 203 in contact with the first-type semiconductor layer may be selected from gold, platinum, or silver, etc., or may be a transparent conductive oxide, and specifically may be ITO, ZnO, etc.; more preferably, the first electrode 203 may be a multilayer material, such as an alloy material including at least one of gold-germanium-nickel, gold-beryllium, gold-germanium, gold-zinc, etc., and more preferably, the first electrode 203 may also include a reflective metal, such as gold or silver, and a portion of the light radiated from the active layer and passing through the current spreading layer 104 of the first-type semiconductor layer may be reflected back to the semiconductor epitaxial stack, and emits from the light exit side.

In order for the second electrode 204 to form good ohmic contact with the second ohmic contact layer 111 of the second-type semiconductor layer, preferably, the material of the second electrode 204 in contact with the second ohmic contact layer 111 may be a conductive metal such as gold, platinum, or silver, more preferably, the second electrode 204 may include a plurality of layers of materials, including at least one alloy material of gold-germanium-nickel, gold-beryllium, gold-germanium, and gold-zinc. More preferably, in order to improve the ohmic contact effect between the second electrode 206 and a side of the second ohmic contact layer 111, at least one metal capable of diffusing to a side of the second ohmic contact layer 111 may be included to improve ohmic contact resistance. In order to promote diffusion, a fusion of 300° C. or more may be selected. The diffusion metal is a metal that may be in direct contact with a side of the second ohmic contact layer 111, such as gold, platinum, or silver.

In order to improve the reliability of the micro light-emitting diode, an insulating protective layer (for example, the insulating protective layer 207 as shown in FIG. 5) may be provided on the first mesa S1, the second mesa S2, and the side walls of the micro light-emitting diode. The insulating protective layer may have a single-layer or multi-layer structure, and may be formed by at least one material of SiO₂, SiNₓ, Al₂O₃, and Ti₃O₅. In some optional embodiments, the insulating protective layer may be a Bragg protective layer structure. For example, the insulating protective layer may be formed by stacking a Ti₃O₅ layer and a SiO₂ layer alternately. In the present embodiment, the material of the insulating protective layer may be SiNx or SiO₂, and the thickness of the insulating protective layer may be 1 μm or more.

In the present embodiment, the first electrode 203 and the second electrode 204 are located at the side of the current spreading layer 104 opposite to the light exit side, and the first electrode 203 and the second electrode 204 may be in contact with corresponding external electrical connecting members located at the side of the current spreading layer 104 opposite to the light exit side, forming a flip-chip structure. Both the first electrode 203 and the second electrode 204 may include an ohmic contact portion and a pad metal layer, and the pad metal layer may include at least one layer of gold, aluminum, or silver, in order to achieve the eutectic bondings of the first electrode 203 and the second electrode 204. The first electrode 203 and the second electrode 204 may be of equal or different height, and the pad metal layers of the first electrode and the second electrode are not overlapped in the thickness direction.

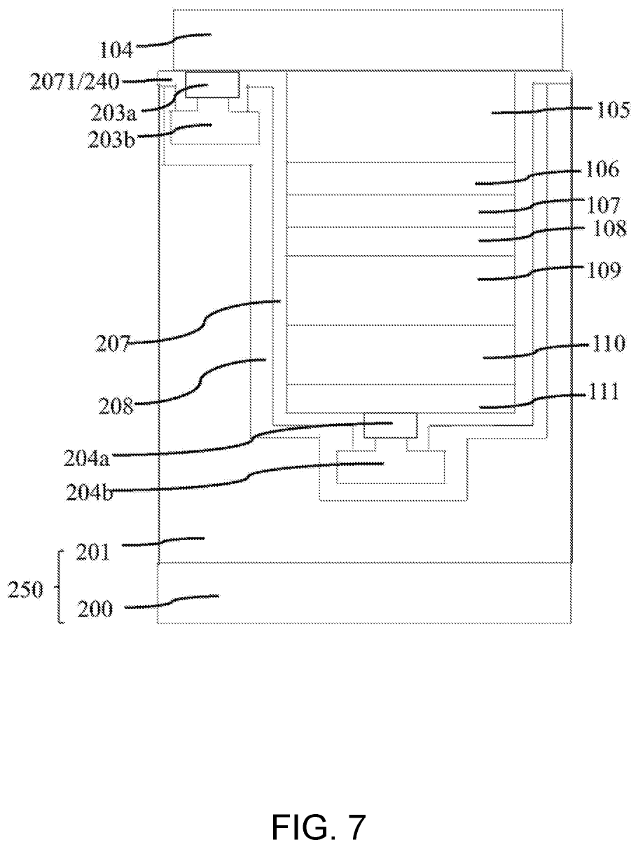

FIG. 7 is a schematic diagram of a micro light-emitting element formed by using the micro light-emitting diode of the present embodiment. The micro light-emitting element also includes a base frame 250 supporting the micro light-emitting diode and a bridge arm 240 connecting the micro light-emitting diode with the base frame 250. The base frame 250 is located at the lower side of the micro light-emitting diode and includes the substrate 200 and the bonding layer 201. The material of the bonding layer 201 in the present embodiment is BCB adhesive, silica gel, UV adhesive, or resin, and the material of the bridge arm 240 includes dielectric, metal, or semiconductor material. In some embodiments, a horizontal portion 2071 of the insulating protective layer 207 may be used as the bridge arm 240 bridging over the bonding layer 201 to connect the micro light-emitting diode with the base frame 250.

The micro light-emitting diode is separated from the base frame 250 by transfer printing using a printing stamp, and the printing stamp material is PDMS, silica gel, pyrolytic adhesive, or UV adhesive. In some situations, there is a sacrificial layer 208 between the micro light-emitting diode and the base frame, and at least in certain situations, the removal efficiency of the sacrificial layer 208 is higher than that of the micro light-emitting diode. The certain situations include chemical decomposition or physical decomposition, such as UV decomposition, etch removal, or shock removal.

### Embodiment 5

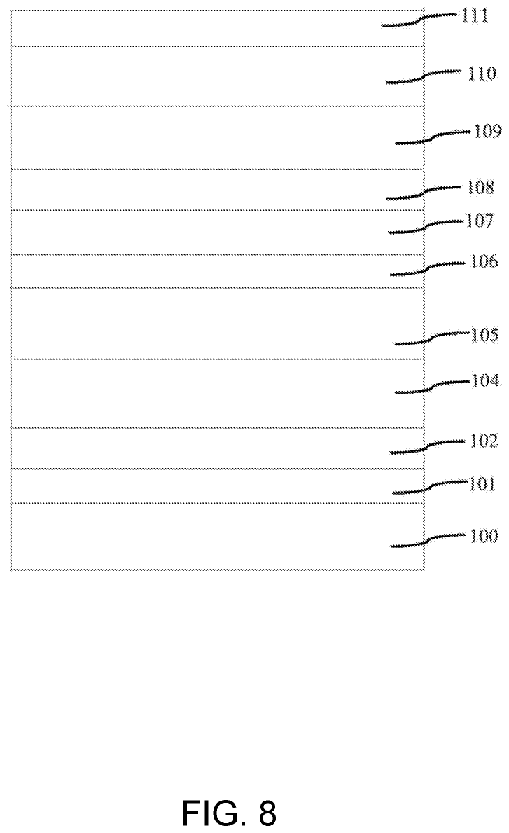

FIG. 8 to FIG. 14 show schematic diagrams of the manufacturing process of the micro light-emitting diode according to Embodiment 4. The manufacturing method of the micro light-emitting diode of the present embodiment is described in detail below with reference to the schematic diagrams.

First, as shown in FIG. 8, an epitaxial structure is provided, specifically including the following steps: the growth substrate 100 is provided, and a semiconductor epitaxial stack is epitaxially grown by an epitaxial process such as MOCVD. The semiconductor epitaxial stack includes the buffer layer 101 and the etch stop layer 102 sequentially stacked on the surface of the growth substrate 100 for removing the epitaxial growth substrate 100, then the growth includes the first current spreading layer 104, the first cladding layer 105, the first spacer layer 106, the active layer 107, the second spacer layer 108, the second cladding layer 109, the second current spreading layer 110, and the second ohmic contact layer 111.

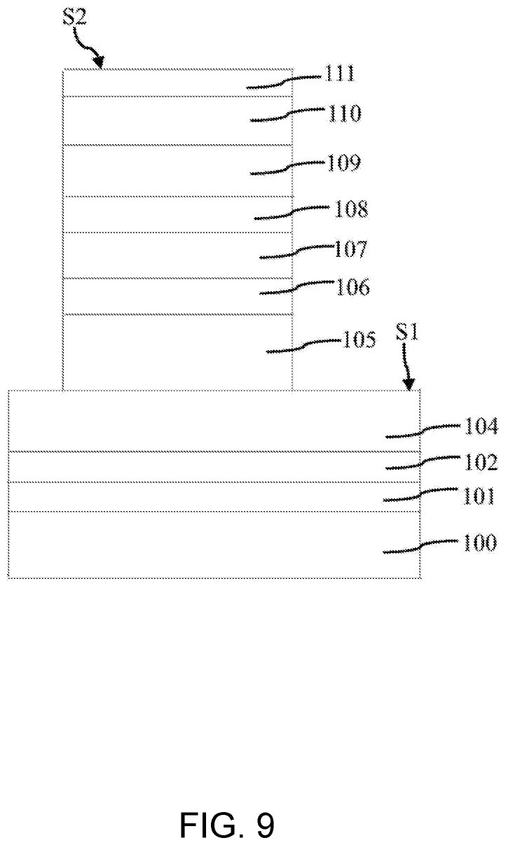

Then, referring to FIG. 9, a portion of the semiconductor epitaxial stack is removed by dry etching to form the first mesa S1 and the second mesa S2. The first mesa S1 is formed by the first-type semiconductor layer exposed by the recess of the semiconductor epitaxial stack, and the second mesa S2 is formed by the second-type semiconductor layer; a sidewall is formed and located at the outer edge of the semiconductor epitaxial stack and located between the first mesa S1 and the second mesa S2.

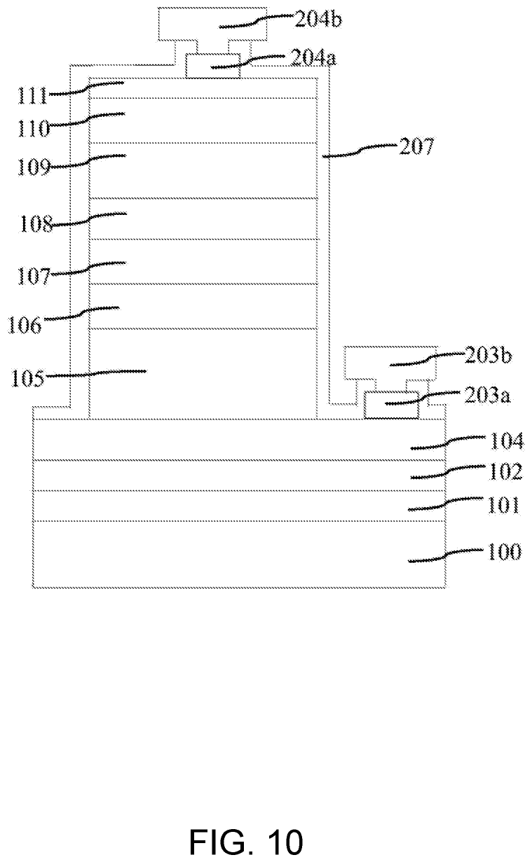

Next, referring to FIG. 10, the first electrode 203 and the second electrode 204 are manufactured on the first mesa S1 and the second mesa S2 respectively; wherein the first electrode 203 and the second electrode 204 include ohmic contact portions 203a and 204a, the insulating protective layer 207 is covered on the ohmic contact portions, and the pad electrodes 203b and 204b are formed in the openings above the insulating protective layer 207 to be in contact with the ohmic contact portions 203a and 204a respectively. The material of the ohmic contact portions 203a and 204a may be, for example, Au/AuZn/Au. In this step, the ohmic contact portions 203a and 204a may be fused to form good ohmic contact with the semiconductor epitaxial stack. The insulating protective layer 207 preferably adopts SiNx or SiO2, and the thickness is 1 μm or more. In other optional embodiments, the insulating protective layer 207 may adopt a Bragg reflective layer structure formed by alternately stacking two materials with different refractive indices.

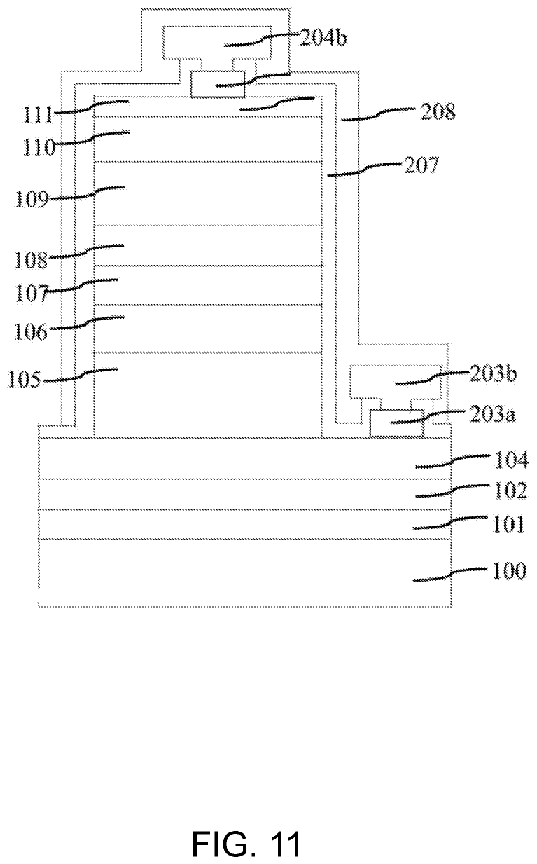

Next, referring to FIG. 11, the sacrificial layer 208 is covered on the surface of the micro light-emitting diode; preferably, the thickness of the sacrificial layer 208 covering the sidewall is 1 μm or more, and the material of the sacrificial layer 208 may be oxide, nitride, or a material that may be optionally removed relative to other layers.

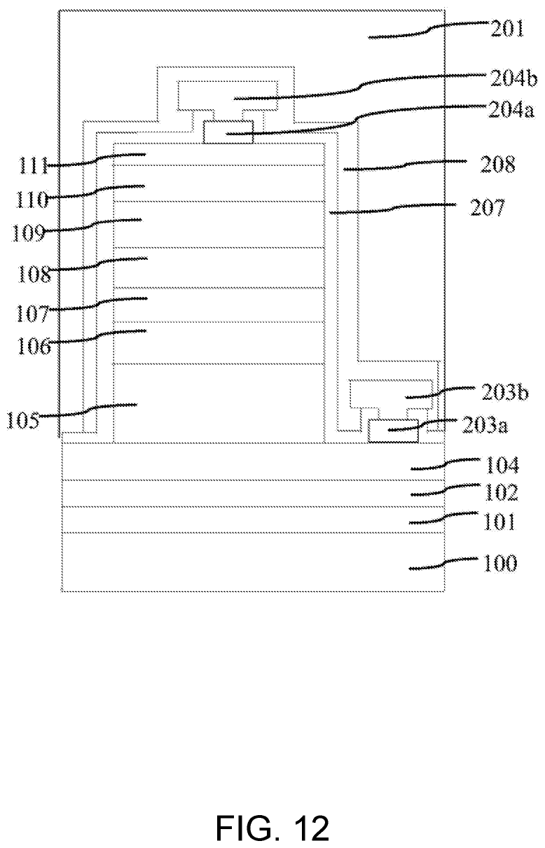

Next, referring to FIG. 12, bonding adhesive such as BCB adhesive is applied on the sacrificial layer 208 of the micro light-emitting diode to form the bonding layer 201.

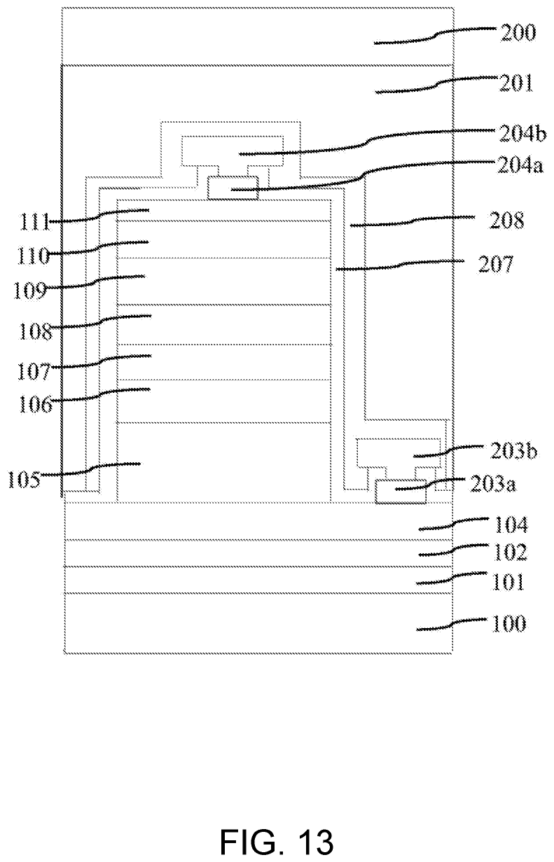

Next, referring to FIG. 13, a wafer distributed with micro light-emitting diodes is bonded on the substrate 200.

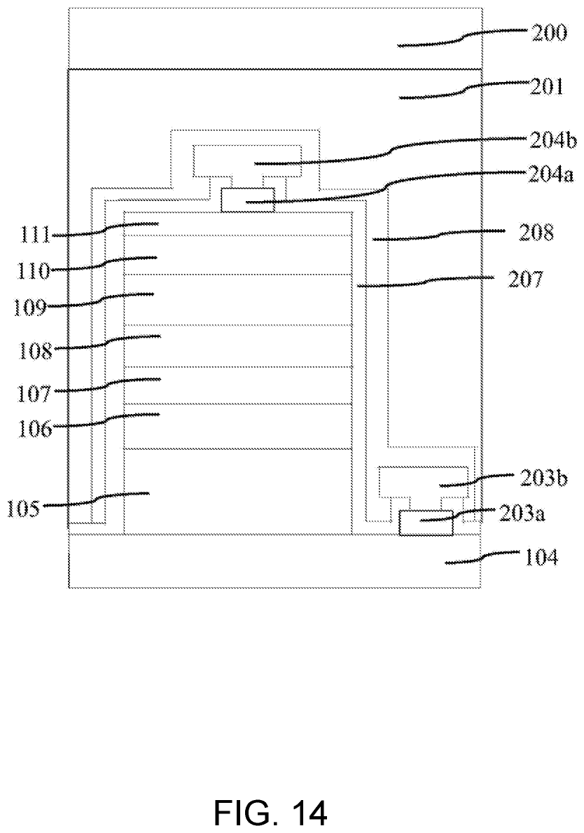

Next, referring to FIG. 14, the growth substrate 100 is peeled off, and the buffer layer 101 and the etch stop layer 102 are removed.

Next, the first-type semiconductor layer at the edge of the micro light-emitting diode is removed by masking and etching, the etching stops on the insulating protective layer 207 to form independent core particles to facilitate the subsequent separation of the core particles, so as to obtain the micro light-emitting diode as shown in FIG. 7.

Lastly, the formed micro light-emitting diode is separated from the substrate 210 by transfer printing and transferred onto a packaging substrate (not shown in the figure).

### Embodiment 6

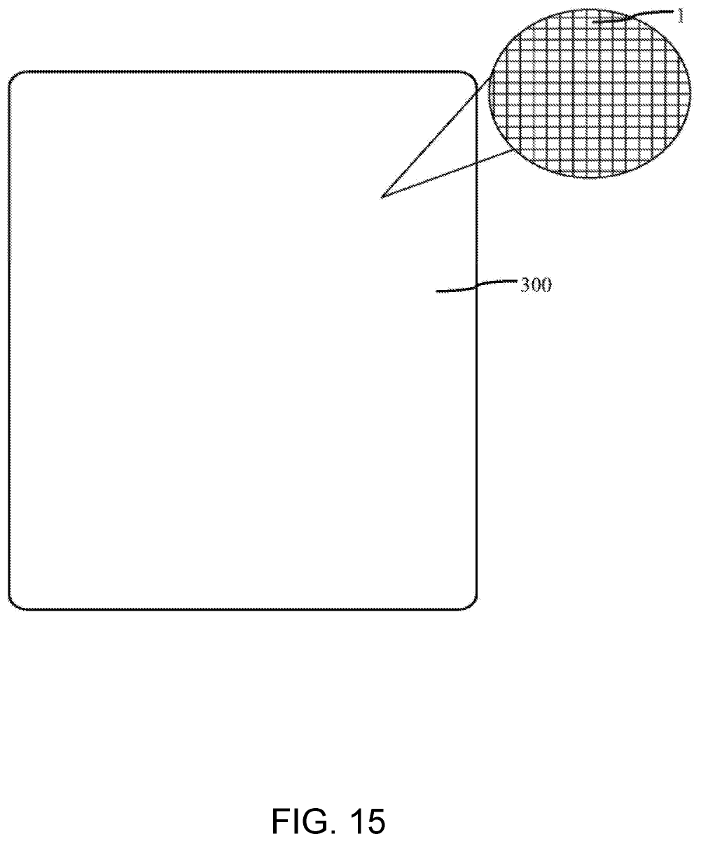

The present embodiment provides a light-emitting device 300. The light-emitting device includes a drive unit and a light-emitting diode, and the drive unit is electrically connected to the light-emitting diode. Please refer to FIG. 15, the light-emitting device 300 includes a plurality of light-emitting diodes arranged in an array as in any of the above embodiments, and a portion of a light-emitting diode 1 is shown in an enlarged schematic manner in FIG. 15.

In the light-emitting diode and the light-emitting device of an embodiment of the invention, the thickness of the first space layer in the light-emitting diode may be designed according to different operating ranges of the current density or chip sizes of the light-emitting diode, in order to implement the more ideal EQE of the light-emitting diode, and further improve the luminous efficiency of the light-emitting device. The light-emitting diode in the light-emitting device may have ideal luminous efficiencies under different operating ranges of current densities.

What is claimed is:

1. A light-emitting diode, comprising:
a semiconductor epitaxial stack having a first surface and a second surface opposite to each other and comprising a first-type semiconductor layer, an active layer, and a second-type semiconductor layer stacked in sequence in a direction from the first surface to the second surface, the active layer comprising n periods of quantum well structure, and each period of quantum well structure comprising a well layer and a barrier layer deposited sequentially;
wherein a first spacer layer is disposed between the first-type semiconductor layer and the active layer, and a ratio of a thickness (nm) of the first spacer layer to a current density (A/cm²) of the light-emitting diode ranges from 0 to 10.

2. The light-emitting diode of claim 1, wherein the ratio of the thickness (nm) of the first spacer layer to the current density (A/cm²) of the light-emitting diode ranges from 0 to 5.

3. The light-emitting diode of claim 1, wherein the thickness of the first spacer layer ranges from 0 nm to 120 nm.

4. The light-emitting diode of claim 1, wherein when the current density of the light-emitting diode is greater than 10 A/cm², the thickness of the first spacer layer ranges from 50 nm to 120 nm.

5. The light-emitting diode of claim 4, wherein a length of at least one side of the light-emitting diode is greater than 100 μm.

6. The light-emitting diode of claim 1, wherein when the current density of the light-emitting diode is less than or equal to 10 A/cm², and the thickness of the first spacer layer ranges from 0 nm to 50 nm.

7. The light-emitting diode of claim 6, wherein a length of at least one side of the light-emitting diode is less than or equal to 100 μm.

8. The light-emitting diode of claim 1, wherein a material of the first spacer layer is AlₐGa₁₋ₐInP, wherein a ranges from 0.2 to 1.

9. The light-emitting diode of claim 1, wherein a doping of the first spacer layer is n-type doping, and a concentration of the n-type doping is less than 2E17/cm³.

10. The light-emitting diode of claim 1, wherein the light-emitting diode further comprises a second spacer layer, and the second spacer layer is located between the active layer and the second-type semiconductor layer.

11. The light-emitting diode of claim 10, wherein a material of the second spacer layer is Al_{b}Ga_{1-b}InP, wherein b ranges from 0.2 to 1.

12. A light-emitting diode, comprising:
a semiconductor epitaxial stack having a first surface and a second surface opposite to each other and comprising a first-type semiconductor layer, an active layer, and a second-type semiconductor layer stacked in sequence in a direction from the first surface to the second surface, the active layer comprising n periods of quantum well structure, each period of quantum well structure comprising a well layer and a barrier layer deposited sequentially, and a first spacer layer being disposed between the first-type semiconductor layer and the active layer;
wherein the light-emitting diode has a first side, a second side, a third side, and a fourth side surrounding in turn, wherein the first side is parallel to the third side, the second side is parallel to the fourth side, a length of the first side is greater than or equal to a length of the second side, and when the length of the second side is greater than 100 μm, a thickness of the first spacer layer ranges from 50 nm to 120 nm, or when the length of the second side is less than or equal to 100 μm, the thickness of the first spacer layer ranges from 0 nm to 50 nm.

13. The light-emitting diode of claim 12, wherein a material of the first spacer layer is AlₐGa₁₋ₐInP, wherein a ranges from 0.2 to 1.

14. The light-emitting diode of claim 12, wherein a doping of the first spacer layer is n-type doping, and a concentration of the n-type doping is less than 2E17/cm³.

15. A light-emitting device, comprising a drive unit and a light-emitting diode, wherein the drive unit is electrically connected to the light-emitting diode, the light-emitting diode has a first surface and a second surface opposite to each other and comprises a first-type semiconductor layer, an active layer, and a second-type semiconductor layer stacked in sequence in a direction from the first surface to the second surface, the active layer comprises n periods of quantum well structure, and each period of quantum well structure comprises a well layer and a barrier layer deposited sequentially;
wherein a first spacer layer is disposed between the first-type semiconductor layer and the active layer, and a ratio of a thickness (nm) of the first spacer layer to a current density (A/cm²) of the light-emitting diode ranges from 0 to 10.

16. The light-emitting device of claim 15, wherein the ratio of the thickness (nm) of the first spacer layer to the current density (A/cm²) of the light-emitting diode ranges from 0 to 5.

17. The light-emitting device of claim 15, wherein when the current density of the light-emitting diode is greater than 10 A/cm², the thickness of the first spacer layer ranges from 50 nm to 120 nm.

18. The light-emitting device of claim 15, wherein when the current density of the light-emitting diode is less than or equal to 10 A/cm², the thickness of the first spacer layer ranges from 0 nm to 50 nm.

19. The light-emitting device of claim 15, wherein a material of the first spacer layer is AlₐGa₁₋ₐInP, and the a ranges from 0.2 to 1.

20. The light-emitting device of claim 15, wherein a doping of the first spacer layer is n-type doping, and a concentration of the n-type doping is less than 2E17/cm³.
